(19) United States
(12) Patent Application Publication
(10) Pub. No.: US 2025/0293205 A1
(43) Pub. Date: Sep. 18, 2025

(54) PROCESSING CORE INCLUDING INTEGRATED HIGH CAPACITY HIGH BANDWIDTH STORAGE MEMORY

(71) Applicant: Western Digital Technologies, Inc., San Jose, CA (US)

(72) Inventors: Nagesh Vodrahalli, Los Altos, CA (US); Rama Shukla, Saratoga, CA (US); Chih Yang Li, Menlo Park, CA (US); Tom Huang, Campbell, CA (US); Shrikar Bhagath, San Jose, CA (US)

(73) Assignee: Western Digital Technologies, Inc., San Jose, CA (US)

(21) Appl. No.: 18/608,695

(22) Filed: Mar. 18, 2024

(51) Int. Cl. H01L 25/065; G11C 11/406; G11C 11/408; H01L 23/00; H01L 23/498

(52) U.S. Cl. CPC H01L 25/0652; G11C 11/406; G11C 11/4087; H01L 23/49838; H01L 24/08; H01L 24/16; H01L 24/97; H01L 2224/08145; H01L 2224/08155; H01L 2224/16146; H01L 2224/16155; H01L 2224/97; H01L 2924/01029; H01L 2924/1431; H01L 2924/1436; H01L 2924/1438

(57) ABSTRACT

A processing core includes a multi-core processor integrated directly onto a high bandwidth, high-capacity memory. The processor may for example be a large graphics processing unit (GPU) or artificial intelligence (AI) processor. The memory may include a non-volatile memory and a volatile memory. The non-volatile memory may comprise a CBA (CMOS bonded to array) memory tile having a single large NAND memory tile coupled together with a CMOS logic circuit tile. The volatile memory may comprise one or more DRAM memory tiles or the like. The processing core may further include stacks of high bandwidth memory (HBM) semiconductor dies affixed to the interposer around one or more sides of the processor, the one or more volatile memory tiles and CBA memory tile.

### BACKGROUND

Processing cores are used for performing calculations, executing instructions and managing components and peripherals to drive the operation of computers and other electronic devices. Typical processing cores include a processor such as a central processing unit that uses non-volatile and/or volatile memory to function. Non-volatile memories may for example comprise stacks of NAND semiconductor dies mounted on a substrate next to the processor or far away from the processor as may be. These semiconductor dies offer large memory capacities, but due in part to their being spaced away from the processor on the circuit board, offer relatively low bandwidth rates, high power requirements and unwanted parasitics. Volatile memories may for example comprise stacks of DRAM semiconductor dies that are specially designed to offer higher bandwidth and smaller power requirements, but at a cost of lower memory capacities in comparison to NAND dies. Traditional processing cores optimize the balance between speed and memory capacity. Typically, DRAM serves as the primary working memory, offering quick access to frequently used data. NAND memory is used for secondary storage, providing ample capacity for long-term data storage but at a slower access speed.

Recently, sophisticated processing cores have been developed including high-speed graphics processing units (GPUs) and/or artificial intelligence (AI) processing devices. GPUs are specialized processors designed to accelerate the rendering and manipulation of images, videos, and complex graphical computations, in part using a multitude of processors operating in parallel. This allows the GPUs to process a large volume of data simultaneously. AI processors are optimized for executing artificial neural networks, again using parallel processing that allows them to process a large volume of data simultaneously.

Specialized processing cores such as GPUs and AI processors have large memory capacity requirements that are not adequately serviced by conventional volatile memories. However, these devices also have high bandwidth and low power requirements that are not adequately serviced by conventional non-volatile memories.

### DESCRIPTION OF THE DRAWINGS

FIG. 1 is a flowchart for forming a processing core according to embodiments of the present technology.

FIG. 2 is a top view of a first semiconductor wafer, and a first semiconductor tile therefrom, according to embodiments of the present technology.

FIG. 3 is a top view of a second semiconductor wafer, and a second semiconductor tile therefrom, according to embodiments of the present technology.

FIG. 4 is a cross-sectional edge view of a first semiconductor tile according to embodiments of the present technology.

FIG. 5 is a cross-sectional edge view of a second semiconductor tile according to embodiments of the present technology.

FIG. 6 is a cross-sectional edge view of a CBA memory tile including a first semiconductor tile bonded to a second semiconductor tile according to embodiments of the present technology.

FIGS. 7-9 are perspective views showing various bump pad patterns on one of the first and second semiconductor tile according to embodiments of the present technology.

FIGS. 10 and 11 are edge and perspective views showing a CBA memory tile according to embodiments of the present technology.

FIG. 12 is a top view of a CBA memory tile including enlarged views of portions of the tile according to embodiments of the present technology.

FIG. 13 is a perspective view of a CBA memory tile mounted on an interposer according to embodiments of the present technology.

FIG. 14 is an exploded perspective view of one or more volatile memories being mounted on the CBA memory tile of FIG. 13 according to embodiments of the present technology.

FIG. 15 is a cross-sectional edge view of a volatile memory tile according to embodiments of the present technology.

FIG. 16 is a perspective view of an integrated processing core including a processor, a CBA memory tile and one or more volatile memories mounted on an interposer according to embodiments of the present technology.

FIG. 17 is a perspective view of a completed processing core including a processor, a CBA memory tile, one or more volatile memories and HBM stacks mounted on an interposer according to embodiments of the present technology.

FIG. 18 is a cross-sectional edge view of the completed processing core of FIG. 16 including a processor, a CBA memory tile, one or more volatile memories and HBM stacks mounted on an interposer according to embodiments of the present technology.

FIG. 19 is an exploded perspective view of a completed processing core including a processor, a CBA memory tile, one or more volatile memories and HBM stacks mounted on an interposer according to embodiments of the present technology.

FIG. 20 is a perspective view of a completed processing core including a processor, a CBA memory tile and one or more volatile memories mounted on an interposer according to alternative embodiments of the present technology.

FIG. 21 is a cross-sectional edge view of the completed processing core of FIG. 20 including a processor, a CBA memory tile and one or more volatile memories mounted on an interposer according to alternative embodiments of the present technology.

FIG. 22 is a perspective view of a completed processing core including a processor, a CBA memory tile and one or more volatile memories according to alternative embodiments of the present technology.

FIG. 23 is a cross-sectional edge view of the completed processing core of FIG. 22 including a processor, a CBA memory tile and one or more volatile memories according to alternative embodiments of the present technology.

FIG. 24 is a perspective view of a completed processing core including a processor and one or more volatile memories according to alternative embodiments of the present technology.

FIG. 25 is a cross-sectional edge view of the completed processing core of FIG. 24 including a processor and one or more volatile memories according to alternative embodiments of the present technology.

FIG. 26 is a top view of a server implementation including an interposer wafer having a number of processing cores according to a further embodiment of the present technology.

FIG. 27 is a cross-sectional edge view of a server implementation including an interposer wafer having a number of processing cores according to a further embodiment of the present technology.

FIG. 28 is a functional block diagram of a CBA memory tile coupled to a processor according to embodiments of the present technology.

### DETAILED DESCRIPTION

The present technology will now be described with reference to the figures, which in embodiments, relate to a processing core including a processor integrated directly onto a high bandwidth high capacity storage memory. The processor may for example be a large graphics processing unit (GPU) or artificial intelligence (AI) processor. The storage memory may include a non-volatile memory and a volatile memory. The non-volatile memory may comprise a CBA (CMOS bonded to array) memory tile having a single large NAND memory tile coupled together with a CMOS logic circuit tile. The volatile memory may comprise one or more DRAM memory tiles or the like. The integrated processor, non-volatile memory and volatile memory may be affixed to an interposer. In embodiments, the processing core may further include stacks of high bandwidth memory (HBM) semiconductor dies affixed to the interposer around one or more sides of the processor and CBA memory tile. However, in embodiments where a sufficient number of non-volatile memory tiles are provided, the HBM semiconductor dies, and even the interposer, may be omitted.

Integrating the processor directly atop large surface area volatile and non-volatile memory tiles allows high bandwidth data transfer directly between the processor and volatile/non-volatile memory tiles, as well as reduced power requirements and parasitics. Moreover, both the non-volatile and volatile memory tiles may be provided with vertical passthrough zones which include no memory elements or CMOS logic circuits. These passthrough zones may include fine-pitch through silicon vias (TSVs) extending vertically through the memory tiles that allow data transfer to/from the processor directly through the volatile and non-volatile memory tiles.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

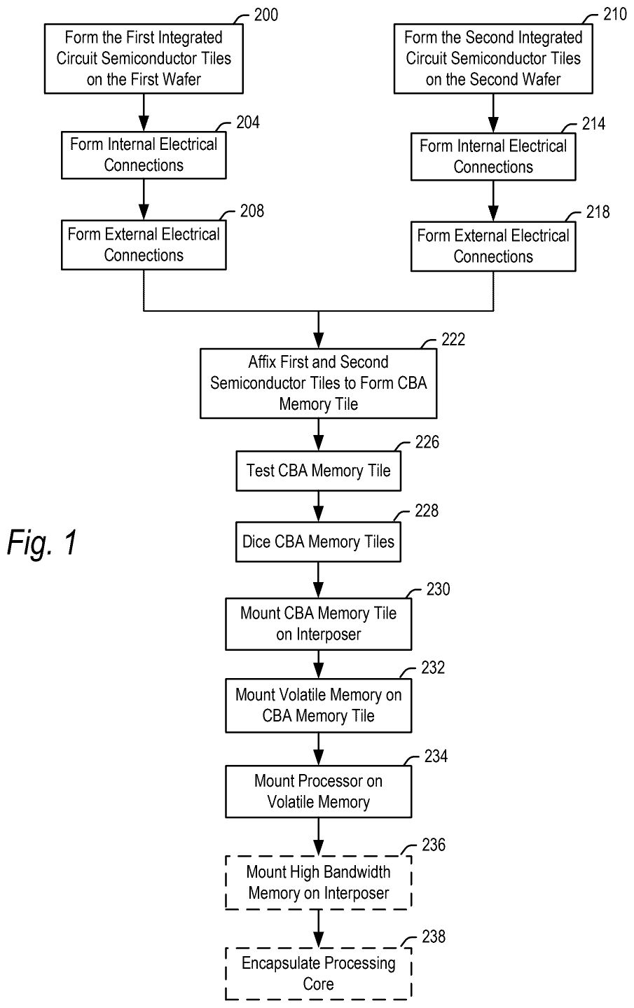

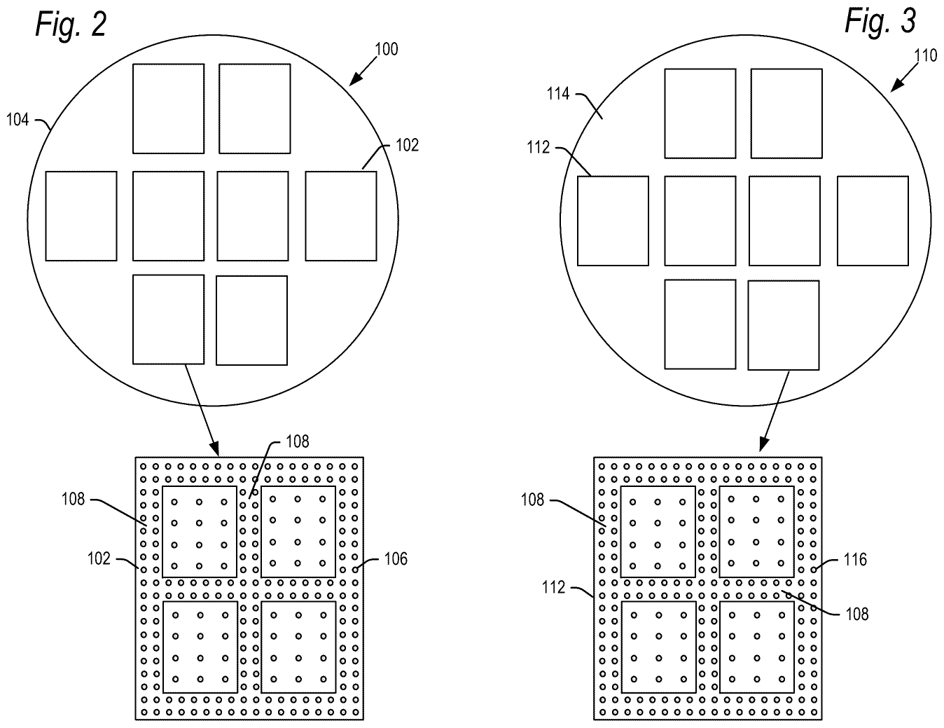

An embodiment of the present technology will now be explained with reference to the flowchart of FIG. 1, and the views of FIGS. 2-27. In step 200, a first semiconductor wafer 100 may be processed into a number of first semiconductor tiles 102 as shown in FIG. 2. The first semiconductor wafer 100 may start as an ingot of wafer material which may be monocrystalline silicon grown according to either a Czochralski (CZ) or floating zone (FZ) process. However, first wafer 100 may be formed of other materials and by other processes in further embodiments.

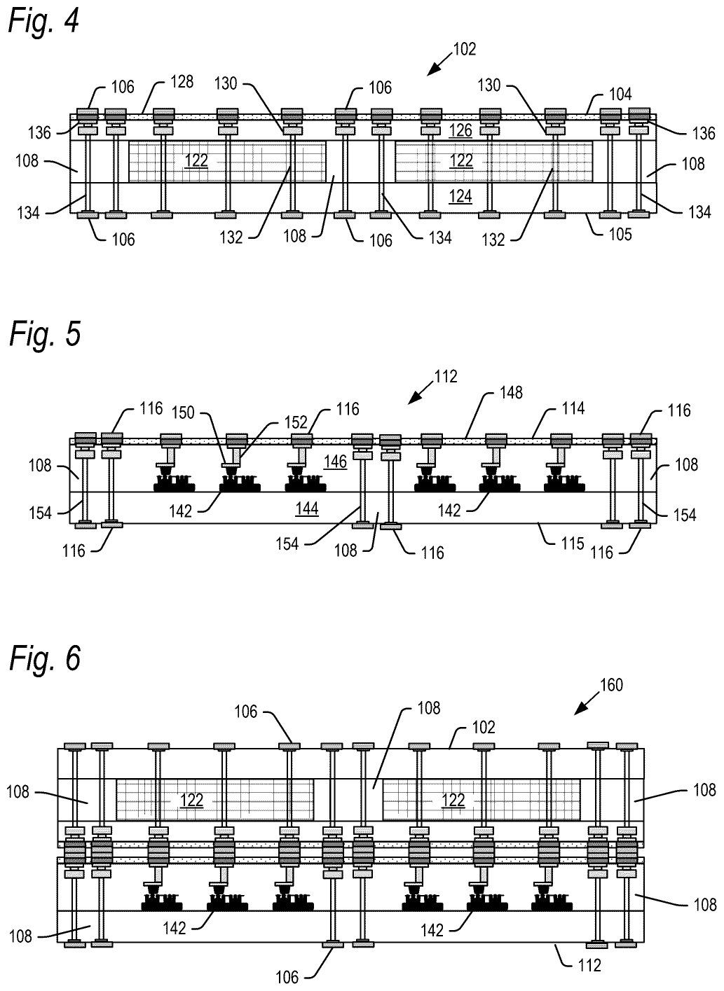

The semiconductor wafer 100 may be cut from the ingot and polished on both the first major planar surface 104, and second major planar surface 105 (FIG. 4) opposite surface 104, to provide smooth surfaces. The first major surface 104 may undergo various processing steps to divide the wafer 100 into the respective first semiconductor tiles 102, and to form integrated circuits of the respective first semiconductor tiles 102 on and/or in the first major surface 104. FIG. 2 further shows detail of a single semiconductor tile 102 including a pattern of micro-bump pads 106 and passthrough zones 108 as explained below.

The processing of wafer 100 in step 200 may include the formation of integrated circuit memory cell array 122 formed in a dielectric substrate including layers 124 and 126 as shown in the cross-sectional edge view of FIG. 4. A reticle may be used to transfer an integrated circuit pattern for a single semiconductor tile 102 in a photolithography process. The patterned wafer can then undergo various processes such as etching, ion implantation, and deposition to create the actual semiconductor components and interconnections needed to build the integrated circuits of a semiconductor tile 102. In embodiments, the integrated circuits may be a memory cell array 122 formed as a 3D stacked memory structure having strings of memory cells formed into layers. However, it is understood that the first semiconductor tile 102 may be processed to include integrated circuits other than a 3D stacked memory structure. A passivation layer 128 may be formed on top of the upper dielectric film layer 126.

Semiconductor processing is trending toward smaller and smaller semiconductor dies. In conventional semiconductor processing, a single reticle may include the pattern for multiple semiconductor dies, and the reticle may be used to define hundreds, if not thousands, of semiconductor dies on a single wafer. The present technology goes counter to this trend. The semiconductor tiles 102 may be the size of an entire reticle, and the reticle is used to form a relatively small number of semiconductor tiles on the wafer 100. As explained below, the size of a semiconductor tile 102 may for example be 32 mm by 25 mm. However, it is understood that the size of a semiconductor tile 102 may vary in further embodiments, and a single reticle may have the pattern for more than one semiconductor tile 102 in further embodiments.

After formation of the memory cell array 122, internal electrical connections may be formed within the first semiconductor tile 102 in step 204. The internal electrical connections may include multiple layers of metal interconnects 130 and vias 132 formed sequentially through layers of the dielectric film 126. As is known in the art, the metal interconnects 130, vias 132 and dielectric film layers 126 may be formed for example by damascene processes a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 130 may be formed of a variety of electrically conductive metals including for example copper and copper alloys as is known in the art, and the vias 132 may be lined and/or filled with a variety of electrically conductive metals including for example tungsten, copper and copper alloys as is known in the art.

As seen for example in FIG. 4, the metal interconnects 130 and vias 132 may be formed to and through the memory cell array 122 to carry signals to and from the memory cell array 122. However, as noted, semiconductor tile 102 may include certain areas, referred to herein as passthrough zones 108, which are devoid of memory cells or other integrated circuits. These zones 108 include TSVs 134. The TSVs 134 may include metal interconnects and vias and may be formed in the same manner as metal interconnects 130 and vias 132 through one or more dielectric layers as described above. In FIGS. 2 and 4, the TSVs 134 and bump pads 106 are more densely packed within the passthrough zones 108, as compared to the interconnects 130, vias 132 and bump pads 106 outside of the zones 108. However, as explained below, the density of the TSVs 134 and bump pads inside the passthrough zones 108 may be the same or less than the density of interconnects 130, vias 132 and bump pads 106 outside of the zones 108.

In step 208, micro-bump pads 106 may be formed on the major planar surfaces 104 and 105 of the first semiconductor tiles 102. As shown in FIGS. 2 and 4, these bump pads may be formed on top of and/or on the bottom of vias 132 and TSVs 134. As is also explained below, the bump pads 106 are provided for transferring signals to and from the semiconductor tile 102. The bump pads may be etched into the passivation layer 128, and each bump pad 106 may be formed over a liner 136. As is known in the art, the bump pads 106 may be formed for example of copper, aluminum and alloys thereof, and the liner 136 may be formed for example of a titanium/titanium nitride stack such as for example Ti/TiN/Ti, though these materials may vary in further embodiments. The bump pads 106 and liner 136 may be applied by vapor deposition and/or plating techniques. The integrated circuit memory arrays 122 may be electrically connected to the bump pads 106 by the metal interconnects 130 and vias 132.

FIG. 2 shows semiconductor tiles 102 on wafer 100, and bump pads 106 in a pattern on one of the semiconductor tiles 102. The number of first semiconductor tiles 102 shown on wafer 100 in FIG. 2 is for illustrative purposes, and wafer 100 may include more or less first semiconductor tiles 102 than are shown in further embodiments. Similarly, the pattern of bump pads 106, as well as the number of bump pads 106, on the first semiconductor tile 102 are shown for illustrative purposes. Each first tile 102 may include more bump pads 106 than are shown in further embodiments, and may include various other patterns and densities of bump pads 106.

Before, after or in parallel with the formation of the first semiconductor tiles on wafer 100, a second semiconductor wafer 110 may be processed into a number of second semiconductor tiles 112 in step 210 as shown in FIG. 3. The semiconductor wafer 110 may start as an ingot of monocrystalline silicon grown according to either a CZ, FZ or other process. The second semiconductor wafer 110 may be cut and polished on both the first major surface 114, and second major surface 115 (FIG. 5) opposite surface 114, to provide smooth surfaces. The first major surface 114 may undergo various processing steps to divide the second wafer 110 into the respective second semiconductor tiles 112, and to form integrated circuits of the respective second semiconductor tiles 112 on and/or in the first major surface 114. FIG. 3 further shows detail of a single semiconductor tile 112 including a pattern of micro-bump pads 116 and passthrough zones 108 as explained below.

In one embodiment, the second semiconductor tiles 112 may be processed to include integrated circuits 142 formed in a dielectric substrate including layers 144 and 146 as shown in the cross-sectional edge view of FIG. 5. Integrated circuits 142 may be configured as logic circuits to control read/write operations for one or more integrated memory cell arrays 122. The logic circuits may be fabricated using CMOS technology, though the logic circuits may be fabricated using other technologies in further embodiments. The second semiconductor tiles 112 may include other and/or additional integrated circuits in further embodiments as explained below. A passivation layer 148 may be formed on top of the upper dielectric film layer 146.

After formation of the CMOS logic circuits 142, internal electrical connections may be formed within the second semiconductor tile 112 in step 204. The internal electrical connections may include multiple layers of metal interconnects 150 and vias 152 formed sequentially through layers of the dielectric film 146. The metal interconnects 150, vias 152 and dielectric film layers 146 may be formed in the same manner as interconnects 130, vias 132 and dielectric film layer 126 described above for tiles 102.

As seen for example in FIG. 4, the metal interconnects 150 and vias 152 may be connected to the CMOS logic circuits 142 to carry signals to and from the logic circuits 142. However, as noted, semiconductor tile 112 may include passthrough zones 108, which are devoid of the CMOS logic or other integrated circuits. The size and pattern of passthrough zones 108 in semiconductor tiles 112 may match the size and pattern of passthrough zones 108 in semiconductor tiles 102. The passthrough zones 108 in tile 112 may include TSVs 154. The number and pattern of TSVs 154 may match the number and pattern of TSVs 134 described above.

In step 208, micro-bump pads 116 may be formed on the major planar surfaces 114 and 115 of the second semiconductor tiles 112. As shown in FIGS. 3 and 5, these bump pads may be on top of and/or below vias 152 and TSVs 154. As is also explained below, the bump pads 116 are provided for transferring signals to and from the semiconductor tile 112. The bump pads may be etched into the passivation layer 148, and may include liners 156. Bump pads 116 and liners 156 may be formed in the same manner as bump pads 106 and liners 136 described above. The CMOS logic circuits 142 may be electrically connected to the bump pads 116 by the metal interconnects 150 and vias 152.

FIG. 3 shows semiconductor tiles 112 on wafer 110, and bump pads 116 in a pattern on one of the semiconductor tiles 112. The number of second semiconductor tiles 112 shown on wafer 110 in FIG. 3 is for illustrative purposes, and wafer 110 may include more or less second semiconductor tiles 112 than are shown in further embodiments. Similarly, the pattern of bump pads 116, as well as the number of bump pads 116, on the second semiconductor tile 112 are shown for illustrative purposes. Each second tile 112 may include more bump pads 116 than are shown in further embodiments, and may include various other patterns and densities of bump pads 116.

Once the fabrication of first and second semiconductor tiles 102 and 112 is complete, the first and second semiconductor wafers 110 and 110 may be affixed to each other in step 222 so that the respective memory tiles 102 are bonded to the CMOS logic circuit tiles 112. Each pair of bonded tiles 102, 112 are referred to herein as a CMOS bonded to array (CBA) memory tile 160. An example of the completed CBA memory tile 160 is shown for example in the cross-sectional edge view of FIG. 6. To bond the tiles 102, 112, the first semiconductor wafer 100 may be flipped over (relative to the view of FIG. 4), and bump pads 106 and 116 of the respective tiles 102 and 112 may be physically and electrically coupled to each other. As shown and noted, the number and pattern of bump pads 106 may match the number and pattern of bump pads 116 so that the pads align with each other when the tiles 102, 112 are coupled together. In embodiments where the number and pattern of bump pads 106, 116 are not symmetrical about a central vertical axis through the tiles, the number and pattern of bump pads 106 may be the mirror image of the number and pattern of bump pads 116 so that the pads 106, 116 align when tile 102 is flipped over.

The first and second semiconductor tiles 102, 112 in the CBA memory tile 160 may be bonded to each other by initially aligning the bump pads 106 and 116 on the respective tiles 102, 112 with each other. Thereafter, the bump pads 106, 116 may be bonded together by any of a variety of bonding techniques, depending in part on bump pad size and bump pad spacing (i.e., bump pad pitch). The bump pad size and pitch may in turn be dictated by the number of electrical interconnections required for the CBA memory tile 160 as explained below.

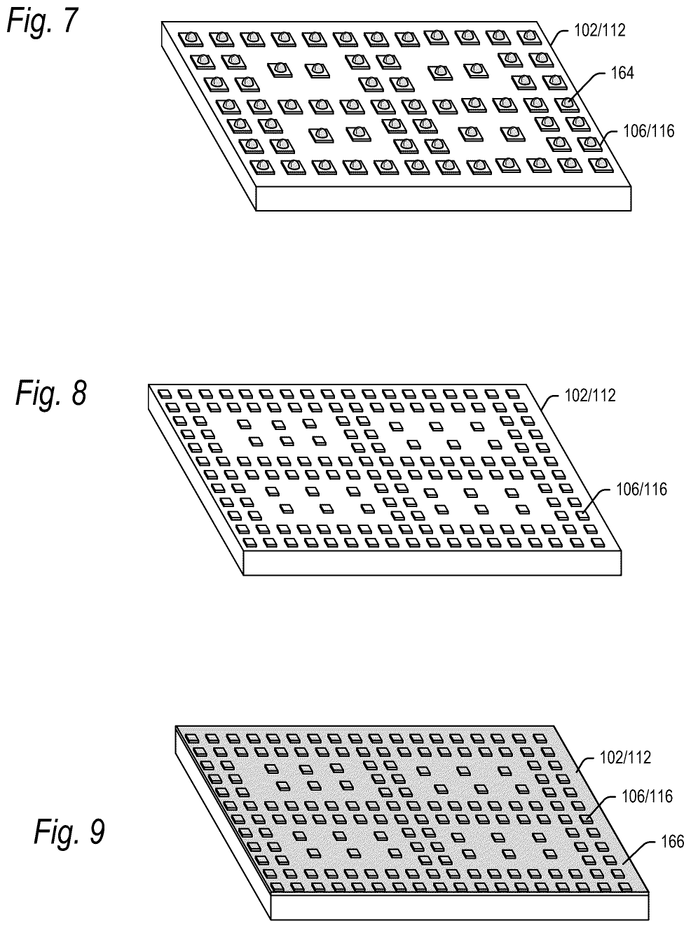

In one embodiment shown in FIG. 7, one or both sets of bump pads 106, 116 on the mating surfaces of the first and second tiles 102, 112 may include micro-bumps 164 applied to the surfaces of pads 106 and/or 116. A small, controlled amount of solder, copper, bronze, gold or other metal may be applied to bump pad 106 and/or to bump pad 116 of a pair of bump pads to be joined. The respective bump pads may be coupled to each other by micro-bumps 164 using for example thermo-compression. In example, the bump pads 106, 116 may be about 50um square. Again, the number and pattern of bump pads 106/116 shown in FIG. 7 is for illustrative purposes only and may vary in further embodiments.

Instead of using micro-bumps 164, the pads 106 and 116 of tiles 102 and 112 may be bonded to each other without solder or other added material, in a so-called Cu-to-Cu bonding process. Such an example is shown in FIG. 8. In a Cu-to-Cu bonding process, the bump pads 106, 116 are controlled to be highly planar and formed in a highly controlled environment largely devoid of ambient particulates. Under such properly controlled conditions, the bump pads 106, 116 are aligned and pressed against each other to form a mutual bond based on oxide bonding. Such bonds may be formed at room temperature, though an annealing process may be performed to heat and cool the bump pads under controlled conditions to further improve the bond. In embodiments using Cu-to-Cu bonding, the bump pads 106, 116 may be about 5 μm square, and the bumps 106, 116 may be spaced from each other with a pitch of 10 μm to 20 μm. The pads and/or pitch may be larger or smaller than that in further embodiments. While this process is referred to herein as Cu-to-Cu bonding, this term may also apply even where the bump pads 106, 116 are formed of materials other than copper.

In a further embodiment shown in FIG. 9, the Cu-to-Cu bond may be enhanced by providing a film layer 166 on the surface 104 of the first tiles 102, and a film layer 166 on the surface 114 of the second tiles 112. Such a film layer 166 is provided around the bump pads 106, 116. When the first and second tiles 102, 112 are brought together, the bump pads 106, 116 may bond to each other using oxide bonding and annealing, and the film layers 166 on the respective tiles may bond to each other using adhesion and/or surface tension. Such a bonding technique may be referred to as hybrid bonding. In embodiments using hybrid bonding, the bump pads 106, 116 may be about 5 μm square, and the bumps 106, 116 may be spaced from each other with a pitch of 5 μm to 10 μm. The pads and/or pitch may be larger or smaller than that in further embodiments.

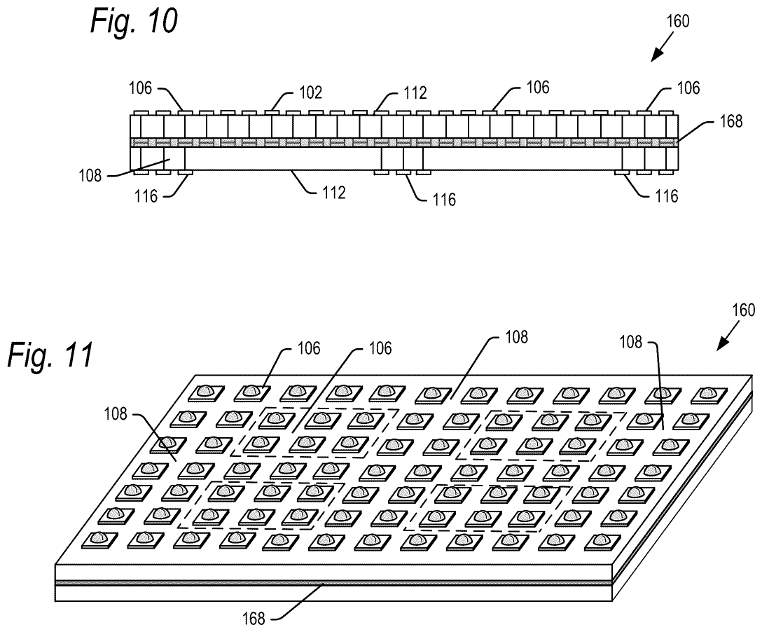

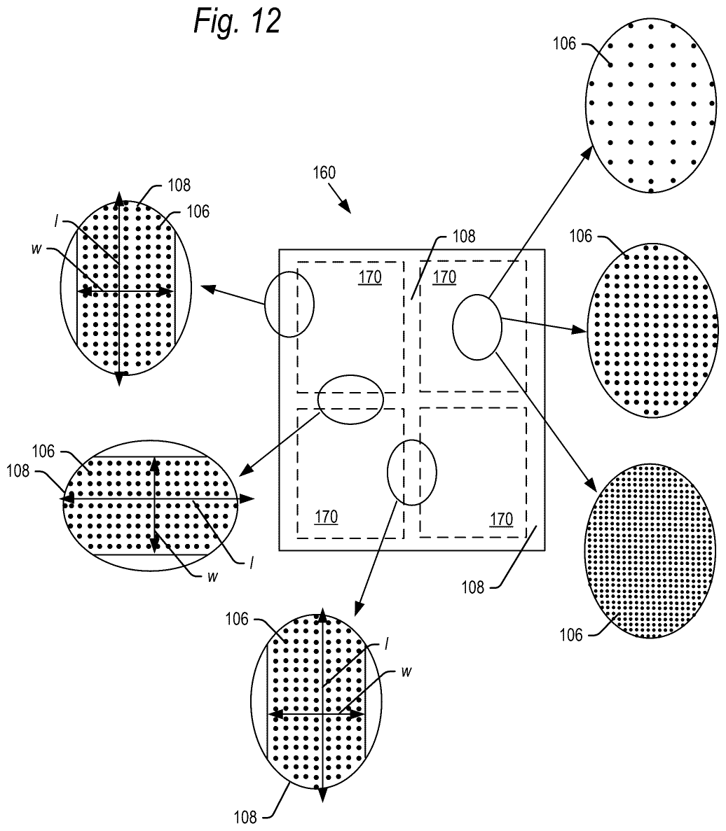

As noted, once coupled to each other in step 222, the first semiconductor tile 102 and the second semiconductor tile 112 together form a CBA memory tile 160. The tile 160 may be operationally tested in step 226 as is known, for example with read/write and burn in operations. The tiles 160 may be diced from the joined wafers 100, 110 in step 228. Examples of the CBA memory tile 160 are shown in the cross-sectional edge view of FIG. 6 described above, as well as in the edge and perspective views of FIGS. 10 and 11. As shown, once coupled together, the bump pads 106 on the surface 105 of tile 102 and the bump pads 116 on surface 115 of tile 112 may remain exposed. These exposed bump pads 106, 116 may be used as explained below. Again, the views of FIGS. 10 and 11 are merely illustrative examples. The number, pattern and/or densities of bump pads 106, 116 shown may vary in further examples.

In one embodiment described above, a film 166 (FIG. 9) may be provided on a surface of one of the first and second tiles 102, 112. Where no such film is initially provided, a space between the first and second tiles of the CBA memory tile 160 may be under filled with an epoxy or other resin or polymer 168 (FIGS. 10 and 11). The under-fill material 168 may be applied as a liquid which then is cured into a solid layer. This under-fill step protects the electrical connections between the first and second tiles 102, 112, and further secures the second tile 112 onto the first tile 102. Various materials may be used as under-fill material 168, but in embodiments, it may be Hysol epoxy resin from Henkel Corp., having offices in California, USA.

As noted above, the CBA memory tile 160 includes passthrough zones 108. These passthrough zones are now explained in greater detail with reference to FIG. 12. In the embodiment shown, the passthrough zones 108 comprise a border around the periphery of tile 160, and a cross pattern extending horizontally and vertically through a center of tile 160. It is understood that the passthrough zones may comprise other patterns on tile 160 in further embodiments. As noted, there are no memory array circuits 122 or logic circuits 142 in the passthrough zones 108.

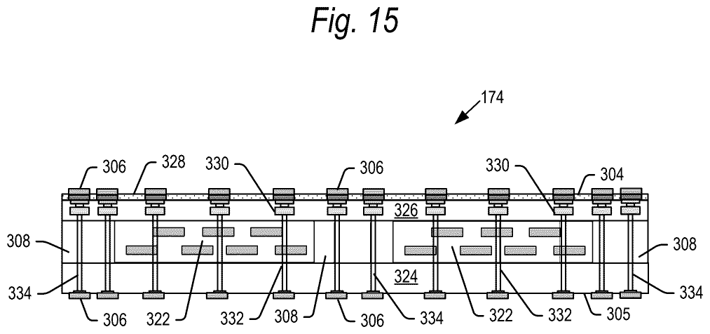

The bump pads 106 in the passthrough zones 108 are used to transfer, or passthrough, power, ground and data signals to and from a processor (see FIG. 15), through the CBA memory tile 160. In one embodiment, as explained below, the passthrough zones 108 around the periphery of tile 160 may be used for signal exchange between the processor and high bandwidth memory also mounted on the interposer, through the tile 160. Given the large numbers of these connections, these periphery passthrough zones 108 may have a width, w, of about 1.25 mm, with 25 rows of bump pads across the width having a pitch of about 40 μm. The pitch of the bump pads along the length, l, may be about 60 μm. In this embodiment, the cross pattern of passthrough zones 108 through the center of the tile 160 may be used for power and ground signals. These cross pattern passthrough zones 108 may have a width, w, of about 500 μm, with 10 rows of bump pads across the width having a pitch of about 50 μm. The pitch of the bump pads along the length, l, may be about 125 μm. Each of these dimensions is by way of example and may vary, proportionately and disproportionately to each other, in further embodiments. It is further understood that the portions of the passthrough zones used for signals, power and ground may also vary in further embodiments.

It is understood that the size of the passthrough zones may be increased or decreased based on the requirements of the processing core. Where more passthrough connections are needed, the size of the passthrough zones may be increased and the number of direct connections between the tile 160 and processor may be decreased. Where less passthrough connections are needed (or more direct connections between the tile 160 and processor are needed), the size of the passthrough zones may be decreased and the number of direct connections between the tile 160 and processor may be increased.

The areas 170 are the areas of tile 160 including the memory array circuits 122 and logic circuits 142, and are positioned outside of passthrough zones 108. In the embodiment shown, the passthrough zones divide the areas 170 into four quadrants. Again, this is one of many possible configurations of the areas 170 including the memory array circuits 122 and logic circuits 142.

As explained below, the CBA memory tile 160 may be mounted on a signal conducting medium, such as a printed circuit board (PCB), a substrate, or an interposer, and a processor may be mounted atop the CBA memory tile 160. The terms PCB, substrate and interposer may be used interchangeably herein, and refer to a means for electrically interconnecting one or more modules or circuits to each other, such as coupling a processor and/or CBA memory tile to one or more semiconductor memory dies. Further, the use of one term over another does not impute specific characteristics to the “signal carrying medium,” such as base materials, number of layers, etc. It is believed that one of skill in the art will be able to understand that where, for instance, the term interposer is used, that interposer also may refer to a substrate or a printed circuit board. The bump pads 116 in the areas 170 allow the processor to be directly coupled to CBA memory tile 160 so that the processor can perform read/write operations to the memory tile 160. Given the large size of the CBA memory tile 160, there is ample room for all of the channels and electrical connections between the processor and CBA memory tile 160. In embodiments, the spacing between, or pitch, of bump pads 106 in the areas 170 may be 2 μm to 50 μm, depending in part on the bonding technology used. Given this pitch and the large surface area of the CBA tile 160, this allows for about 200,000 direct connections between the tile 160 and the processor. The number of direct connections may be more or less than this number in further embodiments. As discussed below, this allows for high bandwidth, wide-word data direct data transfer to and from the CBA memory tile 160. There may be greater or fewer direct connections in further embodiments.

FIG. 12 further shows three enlarged views of alternative densities of the bond pads 106, 116 in the areas 170 to the right of CBA memory tile 160. In the top enlarged view, the density of the pads 106, 116 are less than the densities of the pads 106, 116 in the passthrough zones 108. In the middle enlarged view, the density of the pads 106, 116 are the same as the densities of the pads 106, 116 in the passthrough zones 108. In the bottom enlarged view, the density of the pads 106, 116 are greater than the densities of the pads 106, 116 in the passthrough zones 108. While three enlarged views are shown, the areas 170 would have only one of these three alternative options.

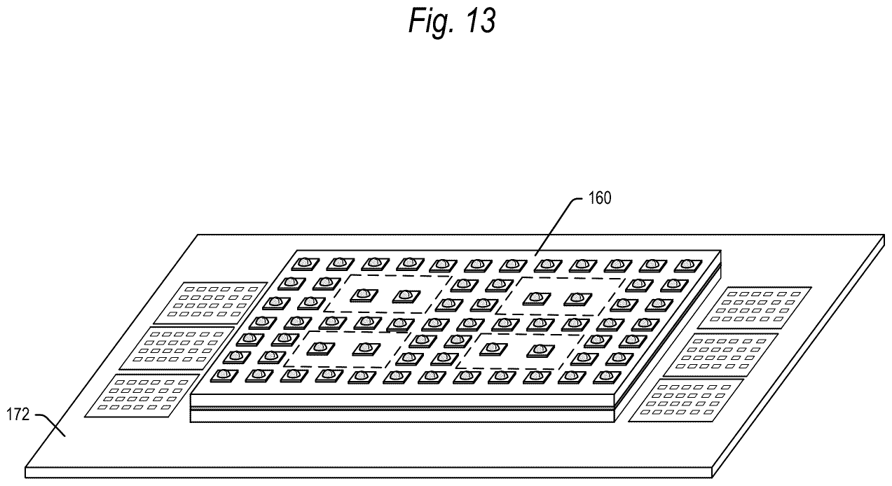

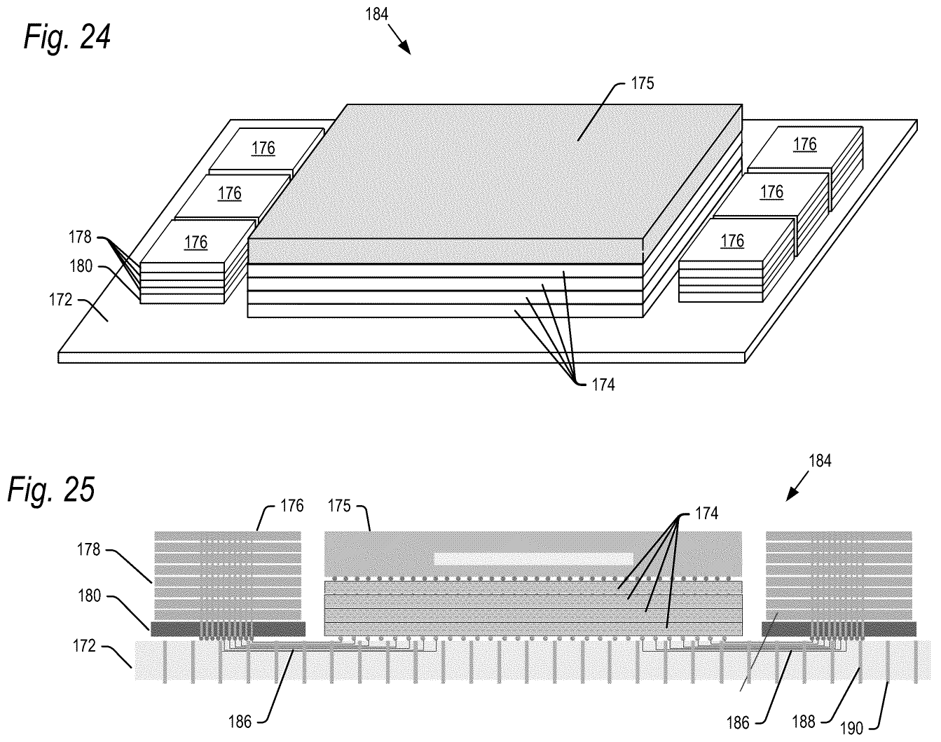

In step 230, the CBA memory tile 160 may be mounted on an interposer 172 as shown in the perspective view of FIG. 13. Interposer 172 may be a signal-carrying medium including multiple conductive layers formed with vias and conductance patterns interspersed between dielectric layers. The interposer may be formed in a silicon wafer, diced into sizes to support the CBA memory tile 160 and high bandwidth memory stacks as explained below. As is also explained below with respect to FIGS. 23 and 24, in further embodiments, the interposer may be left as a whole, undiced wafer. The interposer 172 is used to transfer signals to and from the CBA memory tile 160 and the processor mounted thereon as explained hereinafter. Other signal-carrying mediums may be used in further embodiments, including a flexible tape, a substrate or a printed circuit board.

A top surface of the interposer 172 may have a pattern of contact pads (not shown) matching in number and arrangement to the bump pads 116 on a bottom surface 115 of the CBA memory tile 160. The CBA memory tile 160 may be physically and electrically coupled to the interposer 172 by mating the bump pads 116 on the surface 115 of tile 160 with the contact pads on the upper surface of interposer 172. The bond between the bump pads 116 and contact pads of the interposer may be accomplished using any of the methods described above for bonding bump pads 116 and bond pads 106 within the tile 160.

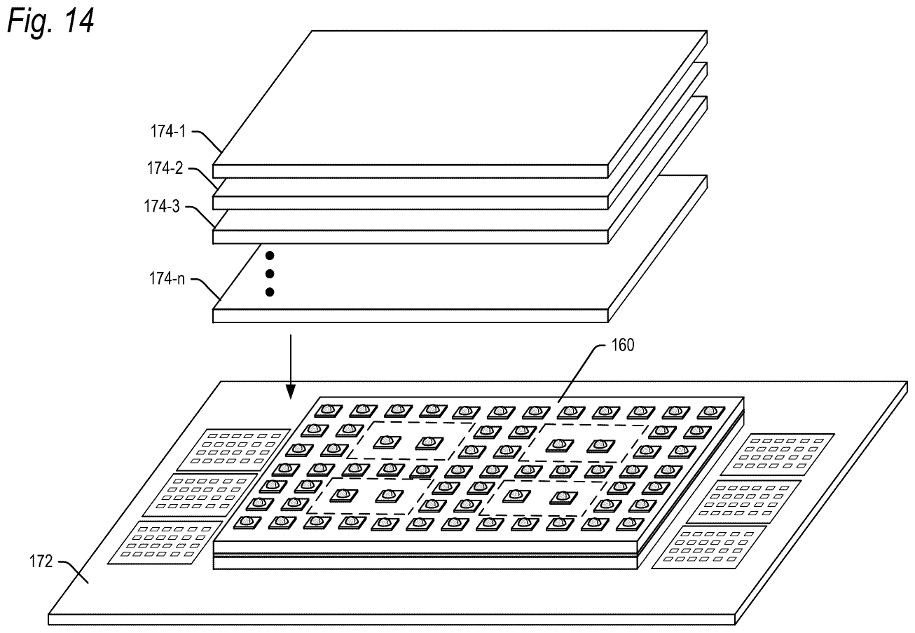

The CBA memory tile 160 provides a large block of memory near to the processor 175 described below, for example 1-4 terabytes. In accordance with aspects of the present technology, one or more volatile memory tiles 174 may be mounted on top of the CBA memory block in step 232 as shown in FIG. 14 to provide a large block of high speed/high bandwidth memory near the processor 175. In embodiments, each volatile memory tile 174 may have the same length and width (same footprint) as the CBA memory tile 160. In the embodiment shown in FIG. 14, the volatile memory tiles 174 may include tiles 174-1, 174-2, 174-3, . . . , 174-n. However, there may be 1, 2, 3, 4 or more tiles 174 in different embodiments.

FIG. 15 is a cross-sectional view of an example of a volatile memory tile 174. The memory tiles may be processed in wafer form to include integrated circuit memory cell array 322 formed in a dielectric substrate including layers 324 and 326. A reticle may be used to transfer an integrated circuit pattern for a single semiconductor tile 174 in a photolithography process. The patterned wafer can then undergo various processes such as etching, ion implantation, and deposition to create the actual semiconductor components and interconnections needed to build the volatile memory integrated circuits of tile 174. In embodiments, the integrated circuit memory cell array 322 may be formed as DRAM including a series of transistors and capacitors. However, the memory cell array 322 may be a variety of other volatiles memories, including for example SRAM, SDRAM and High Bandwidth Memory (HBM). A passivation layer 328 may be formed on top of the upper dielectric film layer 326.

After formation of the memory cell array 322, internal electrical connections may be formed within the volatile memory tile(s) 174. The internal electrical connections may include multiple layers of metal interconnects 330 and vias 332 formed sequentially through layers of the dielectric film 326. The metal interconnects 330 and vias 332 may be formed as described above with respect to metal interconnects 130 and vias 132. As discussed above for CBA tiles 160, the volatile memory tile(s) 174 may include passthrough zones 308, which are devoid of memory cells or other integrated circuits. These zones 308 include TSVs 334 and may match the TSVs 134 in CBA tiles 160 in pattern and configuration. As discussed above, the passthrough zones 308 are provided to allow signals and voltages to pass through the volatile memory tile(s) 174.

Micro-bump pads 306 may be formed on the major planar surfaces 304 and 305 of the volatile memory tile(s) 174. These bump pads may be formed on top of and/or on the bottom of vias 332 and TSVs 334. The micro-bump pads 306 may be formed in the same way and for the same purpose as pads 106 described above. While FIG. 15 shows a pattern of bump pads 306 for illustrative purposes, the pattern of bump pads 306, as well as the number of bump pads 306 may vary in further embodiments.

The bump pads 306 on a bottommost volatile memory tile 174 align with and are bonded to the bump pads 106 on an uppermost surface of the CBA memory tile 160. Moreover, where there are multiple volatile memory tiles 174, the bump pads 306 are used to bond and electrically couple the multiple volatile memory tiles 174 to each other and the CBA memory tile 160.

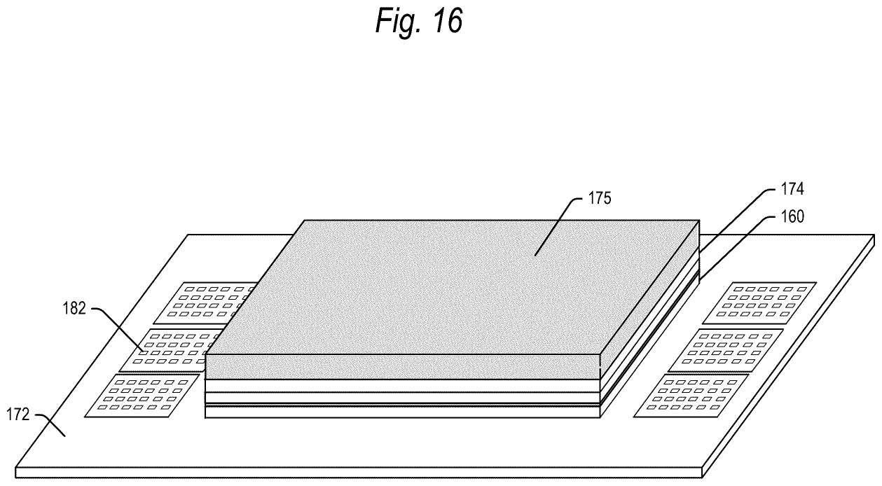

In step 234, a processor 175 may be mounted on top of the one or more volatile memory tiles 174, as shown in the perspective view of FIG. 16, to form an integrated processor/memory core. In embodiments, processor 175 may be a specialized processor such as a graphics processing unit (GPU) or an artificial intelligence (AI) processor capable of parallel processing, sophisticated graphics rendering and/or other high bandwidth, data-intensive tasks. The processor 175 may include multiple processing cores enabling the processor 175 to perform multiple computing tasks simultaneously. In further embodiments, processor 175 may be other types of processors, such a traditional central processing unit.

In embodiments, the processor 175 may have the same footprint as the volatile memory tiles 174 and CBA memory tiles 160. A bottom surface of the processor 175 may have a pattern of contact pads or micro-bumps (not shown) matching in number and arrangement to the bump pads 306 on a top surface of the uppermost volatile memory tile 174. The processor 175 may be physically and electrically coupled to the uppermost volatile memory tile 174 by mating the bump pads of the volatile memory tile with the contact pads on the bottom surface of the processor 175. The bond between the respective bump pads/micro-bumps of the processor 175 and uppermost volatile memory tile may be accomplished using any of the methods described above for bonding of the CBA memory tile 160.

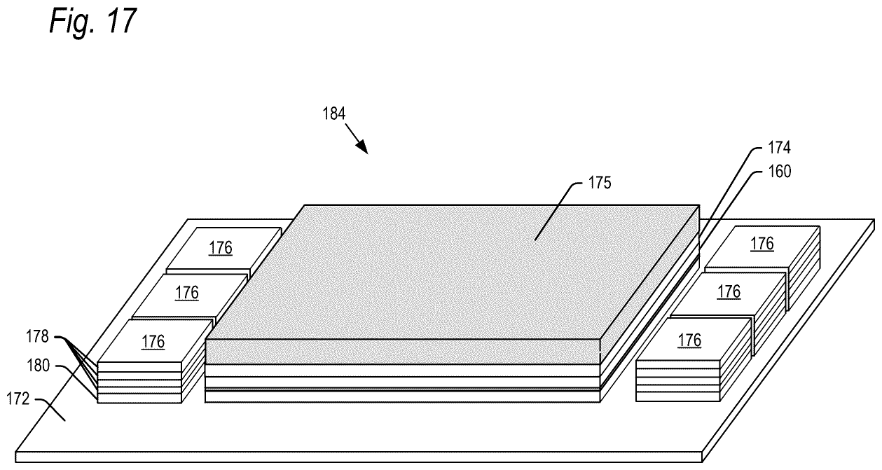

In step 236, high bandwidth memory (HBM) stacks 176 may be mounted around one or more sides of the tiles 160, 174 and processor 175, as shown in the perspective view of FIG. 17. In embodiments, each HBM stack 176 includes one or more HBM dies 178 mounted on a dedicated HBM controller 180. The number of HBM dies 178 in each stack may vary. Embodiments use HBM stacks because HBM is a type of high-speed, high-bandwidth, and low-power memory that is designed to provide fast data access to specialized, high-performance processors, such as the GPU or AI processor which may comprise the processor 175. Other types of memory may be used in stacks 176, including for example DRAM, SRAM, SDRAM or other types of volatile memories. The controller 180 is used to operate and communicate with the dies 178 in each HBM stack 176. While shown at the bottom of each stack in FIG. 17, the controller 180 may be positioned elsewhere in the stack 176 in further embodiments.

In the illustrated embodiment, there are three HBM stacks 176 on each of two opposed sides of the tiles 160, 174 and processor 175. There may be more or less stacks around more or less sides in further embodiments. Each of the dies in stack 176 may be electrically coupled to each other using TSVs, and a bottom surface of the stack 176 may have a pattern of contact pads (not shown) matching in number and arrangement to the contact pads 182 on interposer 172, one of which is numbered in FIG. 16. Each stack 176 may be physically and electrically coupled to pads 182 on interposer 172 as described above with regard to other pad couplings.

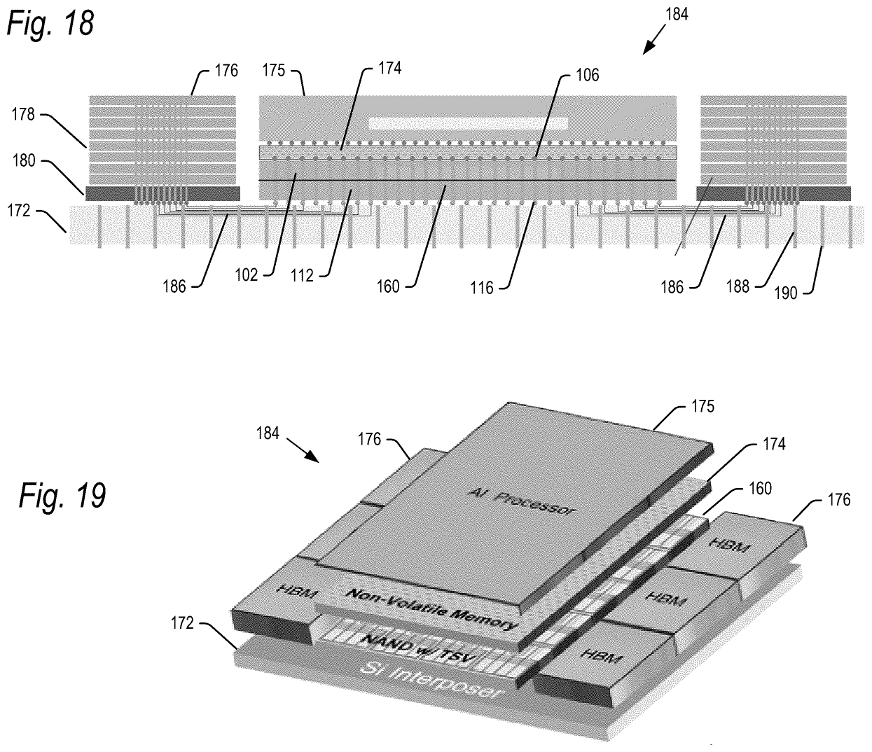

FIG. 17 shows a perspective view of a completed integrated processing core 184 including the integrated CBA memory tile 160, one or more volatile memory tiles 174 and processor 175 together with HBM stacks 176 mounted on interposer 172. FIG. 18 is a cross-sectional view of integrated processing core 184 showing internal electrical connections, and FIG. 19 is a further perspective view of integrated processing core 184. FIG. 18 for example shows the bump pads, such as bump pads 106, between the CBA memory tile 160 and the volatile memory tile 174, and between the volatile memory tile 174 and the processor 175. The drawing further shows the bump pads 116 between the CBA memory tile 160 and the interposer 172. Electrical traces 186 are further shown within layers of the interposer 172 for electrically coupling the processor 175 to the high bandwidth memory stacks 176 (through the passthrough zones of the CBA memory tile 160 and volatile memory tile 174). Also shown are vias 188 through the interposer 172 coupled to pads 190 on a bottom surface of the interposer 172 for electrically coupling the processing core 184 to a printed circuit board of a host device (not shown).

In a final step 238, the entire processing core 184 may be encapsulated in a molding compound. The encapsulation step 238 may be omitted in embodiments. As such, step 238 is shown in dashed lines in FIG. 1. It is noted that the tiles 102, 112 of CBA memory tile 160, volatile memory tile 174, the processor 175 and high-bandwidth semiconductor dies 178 are shown in the figures for illustrative purposes only, and the thicknesses of the respective tiles, processor and high-bandwidth semiconductor dies are not drawn to scale in the figures.

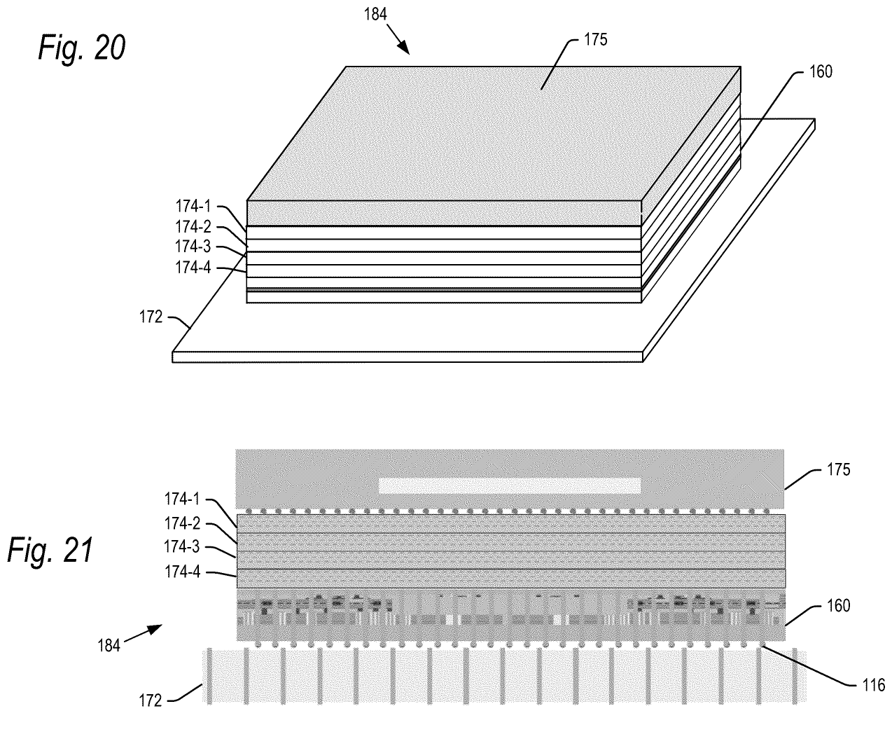

The processing core 184 described above sets forth one example of components, but it is understood that various alternatives and or additions to processing core 184 may be made in further embodiments. For example, in the embodiments described above, the processing core 184 has two ready sources of high bandwidth volatile memory—HBM stacks 176 and volatile memory tile(s) 174. However, where a sufficient number of volatile memory tiles 174 are provided, such as for example four tiles providing 100-200 Gigabytes, the HBM stacks 176 may be partially or completely omitted. As such, step 236 of adding the HBM stacks 176 is shown with dashed lines in FIG. 1. An embodiment where the HBM stacks 176 are completely omitted is shown in perspective view in FIG. 20 and cross-sectional view in FIG. 21.

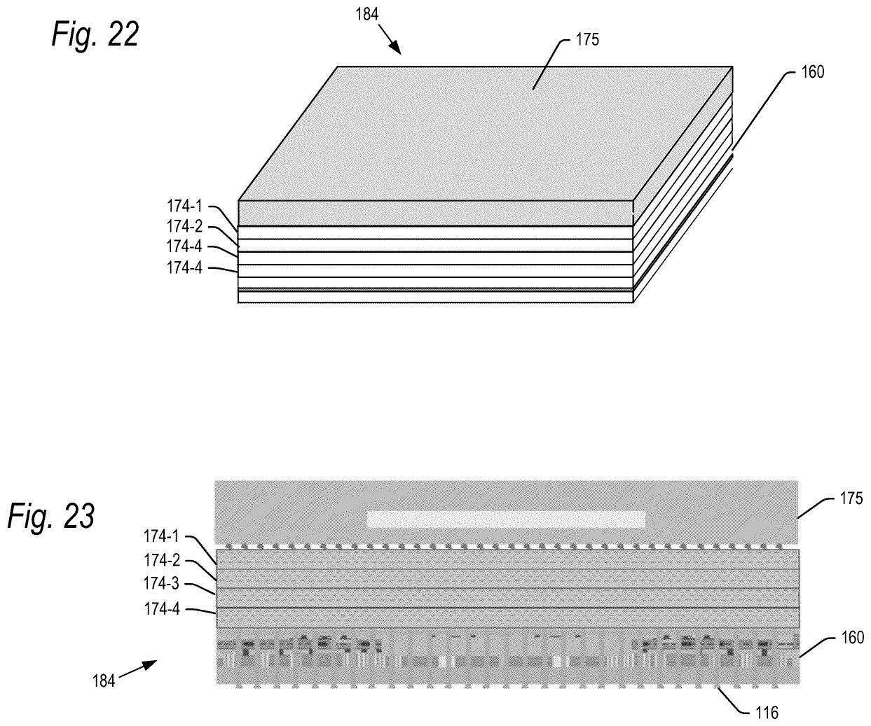

In the embodiment of FIGS. 20 and 21, the integrated processing core 184 is mounted on the interposer 172. However, omission of the HBM stacks 176 also allows omission of the interposer 172. Such an embodiment is shown in perspective view in FIG. 22 and cross-sectional view in FIG. 23. In this embodiment, the CBA memory tile 160 may be configured as a fan-out package (used without a substrate), where the micro-bump pads 116 bottom surface of the CBA memory tile 160 are redistributed (for example by a redistribution layer) to electrically couple the processing core 184 directly to a printed circuit board of a host device (not shown). Omission of the interposer 172 provides advantages such as smaller form factor and lower power requirements.

In a further embodiment, the high speed/high bandwidth volatile memory tiles 174 provide sufficient memory so that the non-volatile CBA memory tile itself may be omitted. Such an embodiment is shown in perspective view in FIG. 24 and cross-sectional view in FIG. 25. In this embodiment, the lowermost volatile memory tile 174 may be mounted directly to the interposer 172, and then the processor 175 may be physically and electrically mounted to the uppermost memory tile 174 as described above. This embodiment may include the HBM stacks 176 as shown in FIGS. 24 and 25, or the HBM stacks 176 may be omitted as shown in FIGS. 20 and 21. Where the HBM stacks are omitted, this embodiment may include the interposer 172 as shown in FIGS. 24 and 25, or the interposer 172 may be omitted as shown in FIGS. 22 and 23.

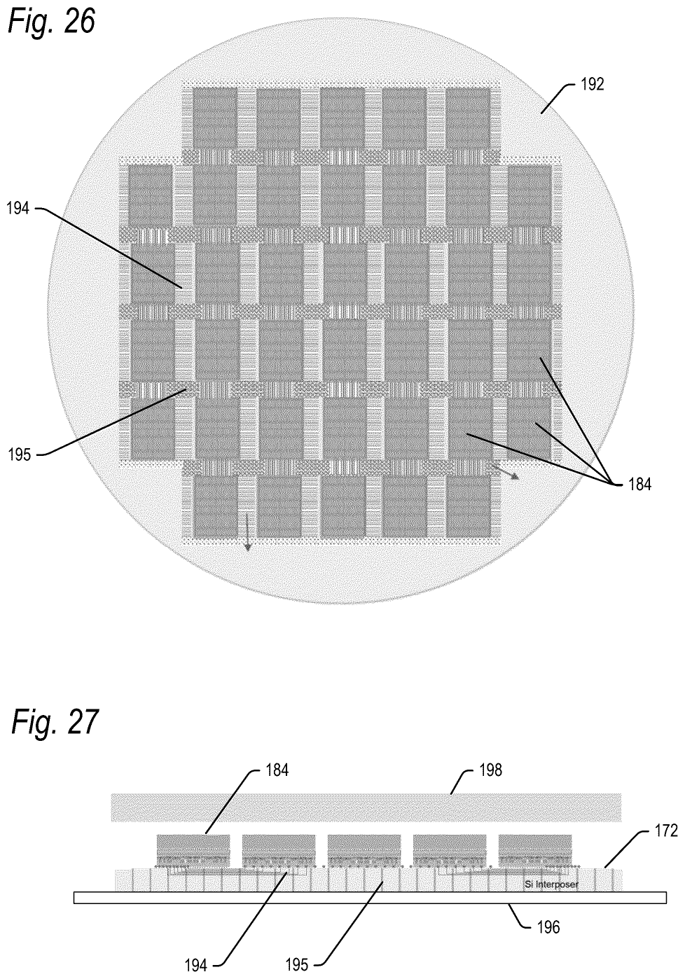

In embodiments described above, the integrated processing core 184 is assembled onto an interposer 172 that has been diced from a wafer of such interposers. A number of the integrated processing cores 184 may be assembled onto a PCB host device, and then racks of such PCB host devices may be used for server and other memory intensive applications. In a further embodiment shown in FIGS. 26 and 27, a number of integrated processing cores 184 may be assembled onto interposers 172 while such interposers remain part of an un-diced silicon-based wafer 192. Each of the integrated processing cores 184 may be assembled on the respective interposers of wafer 192 according to any of the embodiments described above. Each processing core 184 may also be tested prior to assembly onto wafer 192 to ensure that only known good devices are assembled on to wafer 192.

The wafer 192 may include electrical connections 194 and 195 between the respective processing cores 184 and a system level PCB 196. System level PCB 196 may include the passive components and other electrical support for the exchange of signals and data to/from the respective processing cores 184 on wafer 192. The electrical connections 194 may be implemented as traces and/or vias defined within the wafer 192 electrically connecting the respective processing cores 184 to each other. The electrical connections 195 may be vias (or vias and traces), for electrically connecting the respective processing cores to the system level PCB 196, on which the wafer 192 may for example be mounted. The vias for electrically connecting the respective processing cores to the system level PCB 196 may for example be the vias 188 described above within the interposer 172.

Assembling the multiple processing cores 184 onto a single interposer wafer 192 provides a highly efficient server implementation, where densely package cores 184 may be electrically coupled to each other and the system level PCB 196 by a series of electrical interconnections 194 and 195. The electrical interconnections 194, 195 may be defined in an efficient pattern during the formation of wafer 192 by any of the processes shown and described above for example in FIGS. 2-5 with respect to the formation of wafers 100, 110.

The dense packing of the processing cores 184 on wafer 192 generates heat, which may be removed by way of a thermal management system 198, shown schematically in FIG. 27. In embodiments, the thermal management system 198 may comprise a series of high thermal conductivity plates and/or tubes through which a cold liquid runs to draw heat away from the processing cores 184 by conduction. In embodiments, the plates and/or tubes of the thermal management system 198 may lie adjacent or in contact with an upper surface of the processing cores 184. In further embodiments, heat sinks may be mounted to the upper surfaces of the each of the processing cores 184, which heat sinks lie adjacent or in contact with the thermally conductive plates and/or tubes of the thermal management system 198.

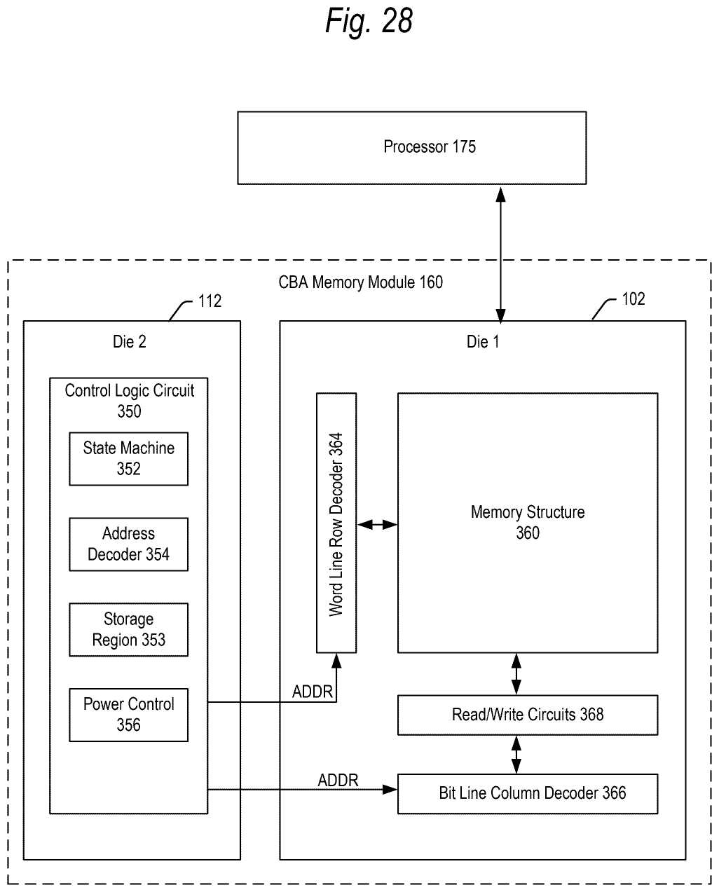

FIG. 28 is a functional block diagram showing further detail of an embodiment of the processing core 184 including CBA memory tiles having memory array tile 102 and CMOS logic circuit tile 112. The memory array tile 102 of the CBA memory tile 160 may include a memory structure 360 of memory cells, such as an array of memory cells, and read/write circuits 368. The CMOS logic circuit tile 112 may include control logic circuitry 350. The memory structure 360 is addressable by word lines via a row decoder 364 and by bit lines via a column decoder 366. The read/write circuits 368 may include multiple sense blocks (sensing circuitry) that allow a page of memory cells to be read or programmed in parallel.

Multiple memory elements in memory structure 360 may be configured so that they are connected in series or so that each element is individually accessible. By way of non-limiting example, flash memory systems in a NAND configuration (NAND memory) typically contain memory elements connected in series. A NAND string is an example of a set of series-connected transistors comprising memory cells and select gate transistors.

A NAND memory array may be configured so that the array is composed of multiple strings of memory in which a string is composed of multiple memory elements sharing a single bit line and accessed as a group. Alternatively, memory elements of memory structure 160 may be configured so that each element is individually accessible, e.g., a NOR memory array. NAND and NOR memory configurations are exemplary, and memory elements may be otherwise configured.

The memory structure 360 can be two-dimensional (2D) or three-dimensional (3D). The memory structure 360 may comprise one or more arrays of memory elements (also referred to as memory cells). A 3D memory array is arranged so that memory elements occupy multiple planes or multiple memory device levels, thereby forming a structure in three dimensions (i.e., in the x, y and z directions, where the z direction is substantially perpendicular and the x and y directions are substantially parallel to the major planar surface of the first semiconductor tile 102).

The memory structure 360 on the first tile 102 may be controlled by control logic circuit 350 on the second tile 112. The control logic circuit 350 may have circuitry used for controlling and driving memory elements to accomplish functions such as programming and reading. The control circuitry 350 cooperates with the read/write circuits 368 to perform memory operations on the memory structure 360. In embodiments, control circuitry 350 may include a state machine 352, an on-chip address decoder 354, and a power control module 356. The state machine 352 provides chip-level control of memory operations. A storage region 353 may be provided for operating the memory structure 360 such as programming parameters for different rows or other groups of memory cells. These programming parameters could include bit line voltages and verify voltages.

The on-chip address decoder 354 provides an address interface between that used by the host device or the memory controller (explained below) to the hardware address used by the decoders 364 and 366. The power control module 356 controls the power and voltages supplied to the word lines and bit lines during memory operations. It can include drivers for word line layers in a 3D configuration, source side select gates, drain side select gates and source lines. A source side select gate is a gate transistor at a source-end of a NAND string, and a drain side select gate is a transistor at a drain-end of a NAND string.

A processing core 184 including an integrated processor 175, CBA memory tile 160 and/or volatile memory tile(s) 174 provides several advantages. For example, the large size of the non-volatile and volatile memory tiles, matching the size of the processor 175, provides a large memory storage for the processor. In examples, this storage capacity may be about 2 terabytes of storage, which is ample storage for even sophisticated processors such as a GPU or AI processor.

As another advantage, the large surface area of the volatile memory tile(s) 174 in direct contact with processor 175, and the small pitch electrical connections over this area, allow for a large number of direct electrical connections resulting in high bandwidth data transfer between the volatile memory tile(s) 174 and processor 175. In examples, the high number of direct electrical connections allow for wide-word data transfer between the volatile memory tile(s) 174 and the processor 175, providing for example 1024 bit data transfer between the volatile memory tile(s) 174 and processor 175. The same high bandwidth rates may be accomplished between the processor 175 and the CBA memory tile 160. This high bandwidth data transfer supports the parallel processing and high performance needs of sophisticated processors such as a GPU or AI processor. Integrating the processor 175 directly atop the large surface area volatile memory tile(s) 174 and CBA memory tile 160 further provides reduced power requirements and parasitics as compared to conventional processing cores where the non-volatile memory is located remote from the processor.

As another advantage, the TSVs in the passthrough zones allow wide-word data transfer between the processor 175 and the HBM stacks 176, again supporting high bandwidth data transfer between the processor 175 and the HBM stacks 176.

A still further advantage of the present technology is that, given the large size of the CBA memory tile 160, and in particular, the large size of the CMOS logic circuit tile 112, only a small portion of the CMOS logic circuit tile 112 is needed to support the operation of the memory array tile 102. As a result, it is conceivable that certain processing functions of the processor 175 can be offloaded to the CMOS logic circuit tile 112 in addition to the memory management processes normally performed by CMOS logic circuits.

In embodiments described above, the first and second wafers 100, 110 may be diced after formation and bonding of the memory array tiles 102 and CMOS logic circuit tiles 112. The formed CBA memory tile 160 may thereafter be bonded to a processor 175 as described above to form an integrated processing core. In further embodiments, instead dicing one or both wafers 100, 110, the wafers may be used as a whole. For example, the wafers 100, 110 may be formed and bonded together to form a single large CBA memory wafer. Thereafter, multiple processors 175 may be bonded on top of the CBA memory wafer.

In summary, an example of the present technology relates to a processing core, comprising: a signal-carrying medium; one or more volatile memory tiles electrically coupled to the signal carrying medium; a processor physically and electrically coupled to an uppermost volatile memory tile of the one or more volatile memory tiles.

In another example, the present technology relates to a processing core, comprising: a signal-carrying medium; one or more volatile memory tiles electrically coupled to the signal-carrying medium, a volatile memory tile of the one or more volatile memory tiles comprising: a first area comprising integrated memory circuits, and one or more passthrough zones outside of the first area, the passthrough zones devoid of the integrated memory circuits; and a processor physically and electrically coupled to an uppermost volatile memory tile of the one or more volatile memory tiles; wherein the volatile memory tile further comprises: a first set of electrical connections in the first area electrically coupling the volatile memory tile to the processor, and a second set of electrical connections in the one or more passthrough zones configured to transfer electrical signals between the processor and signal-carrying medium through the volatile memory tile.

In a further example, the present technology relates to a semiconductor wafer processed to include circuitry for a plurality of interposers, comprising: a plurality of processing cores formed on the plurality of interposers, a processing core of the plurality of processing cores comprising: a CMOS bonded to array (CBA) memory tile physically and electrically coupled to the interposer, the CBA memory tile comprising a memory array tile comprising non-volatile memory arrays, and a CMOS logic circuit tile comprising CMOS logic circuits bonded to the memory array tile; one or more volatile memory tiles physically and electrically coupled to the CBA memory tile; and a processor physically and electrically coupled to an uppermost volatile memory tile of the one or more volatile memory tiles.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A processing core, comprising:
a signal-carrying medium;
one or more volatile memory tiles electrically coupled to the signal carrying medium;
a processor physically and electrically coupled to an uppermost volatile memory tile of the one or more volatile memory tiles.

2. The processing core of claim 1, wherein the one or more volatile memory tiles are one of a DRAM, SRAM, SDRAM and a high bandwidth memory.

3. The processing core of claim 1, wherein the one or more volatile memory tiles have a same footprint as the processor.

4. The processing core of claim 1, further comprising one or more stacks of high bandwidth memory mounted on the signal-carrying medium around one or more lateral sides of the CBA memory tile.

5. The processing core of claim 1, wherein the processor comprises one or more processing cores.

6. The processing core of claim 1, wherein the processor is one of a graphics processing unit and an artificial intelligence processor.

7. The processing core of claim 1, further comprising a CMOS Bonded Array (CBA) memory tile physically and electrically coupled to the signal carrying medium, the memory tile comprising a first semiconductor tile bonded to a second semiconductor tile, wherein a bottommost volatile memory tile of the one or more memory tiles is physically and electrically coupled to the CBA memory tile.

8. The processing core of claim 7, wherein the first semiconductor tile comprises a plurality of memory cells.

9. The processing core of claim 8, wherein the second semiconductor tile comprises a CMOS logic circuit for controlling access to the plurality of memory cells.

10. The processing core of claim 7, wherein the first semiconductor tile is bonded to the processor and the second semiconductor tile is coupled to the signal-carrying medium.

11. The processing core of claim 7, wherein the CBA memory tile is the same footprint as the one or more non-volatile memories and the processor.

12. A processing core, comprising:
a signal-carrying medium;
one or more volatile memory tiles electrically coupled to the signal-carrying medium, a volatile memory tile of the one or more volatile memory tiles comprising:
a first area comprising integrated memory circuits, and
one or more passthrough zones outside of the first area, the passthrough zones devoid of the integrated memory circuits; and
a processor physically and electrically coupled to an uppermost volatile memory tile of the one or more volatile memory tiles;
wherein the volatile memory tile further comprises:
a first set of electrical connections in the first area electrically coupling the volatile memory tile to the processor, and
a second set of electrical connections in the one or more passthrough zones configured to transfer electrical signals between the processor and signal-carrying medium through the volatile memory tile.

13. The processing core of claim 12, wherein the signal-carrying medium is an interposer diced from an interposer wafer.

14. The processing core of claim 12, wherein the signal-carrying medium is a wafer comprising a plurality of interposers, the processing core mounted to one of the interposers on the wafer of interposers.

15. The processing core of claim 12, further comprising a CMOS bonded to array (CBA) memory tile physically and electrically coupled to the signal carrying medium, the CBA memory tile comprising a memory array tile comprising non-volatile memory arrays, and a CMOS logic circuit tile comprising CMOS logic circuits bonded to the memory array tile.

16. The processing core of claim 15, wherein the CBA memory tile comprises a second area comprising the non-volatile memory arrays and the CMOS logic circuits, and a second passthrough zone, aligning with the first passthrough zone of the volatile memory tile, wherein the second passthrough zone is configured to transfer electrical signals between the processor and signal-carrying medium through the CBA memory tile.

17. The processing core of claim 15, wherein the CBA memory tile, the one or more volatile memory tiles and the processor have the same footprint.

18. The processing core of claim 17, wherein the footprint is a size of a reticle used to define the integrated memory circuits of the volatile memory tile.

19. A semiconductor wafer processed to include circuitry for a plurality of interposers, comprising:
a plurality of processing cores formed on the plurality of interposers, a processing core of the plurality of processing cores comprising:
a CMOS bonded to array (CBA) memory tile physically and electrically coupled to the interposer, the CBA memory tile comprising a memory array tile comprising non-volatile memory arrays, and a CMOS logic circuit tile comprising CMOS logic circuits bonded to the memory array tile;
one or more volatile memory tiles physically and electrically coupled to the CBA memory tile; and
a processor physically and electrically coupled to an uppermost volatile memory tile of the one or more volatile memory tiles.

20. The semiconductor wafer of claim 19, wherein the circuitry includes a first set of electrical connections electrically coupling the plurality of processing cores to each other, and a second set of electrical connections configured to electrically coupling the wafer to system level PCB.
